(19) United States
(12) Patent Application Publication
(10) Pub. No.: US 2010/0097087 A1
(43) Pub. Date: Apr. 22, 2010

(54) EYE MAPPING BUILT-IN SELF TEST (BIST) METHOD AND APPARATUS

(75) Inventors: John Hogeboom, Ottawa (CA); Davide Tonietto, Ottawa (CA)

Correspondence Address: STMICROELECTRONICS, INC., MAIL STATION 2346, 1310 ELECTRONICS DRIVE, CARROLLTON, TX, 75006, US

(73) Assignee: STMicroelectronics, Inc., Carrollton, TX (US)

(21) Appl. No.: 12/254,397

(22) Filed: Oct. 20, 2008

(51) Int. Cl. G01R 31/3187

(52) U.S. Cl. 324/763

(57) ABSTRACT

A built-in self test for receiver operation is provided through a testing method that evaluates characteristics of a received signal eye diagram. The receiver receives a serial data signal and applies compensation to that received serial data signal to generate a compensated serial data signal. The properties of an eye diagram associated with the compensated serial data signal are measured. In this context, certain desired eye diagram properties are characterized by parameters indicative of pass/fail criteria for receiver testing. The measured eye diagram properties are then compared against the parameters. A receiver testing conclusion signal is then output based on results of the comparison.

### TECHNICAL FIELD

The present invention relates to communications devices and systems and, more particularly, to a built-in self test (BIST) functionality based on an eye mapping technique.

### BACKGROUND

High speed SERDES (SERializer/DE-Serializer) elements are a key component in modern high performance digital communication systems and digital interfaces in computer systems. The nature of electronics makes electrical signals the most fundamental and preferred signal transmission technique, giving such signals an advantage over other signal forms, such as optical, which need to be converted to and from the electrical form with significant penalties in cost, power, and complexity. In most cases optical signaling is viable when long distances are involved. However, there is little practical alternative to electrical signals for internal communication within localized electronic systems.

Other than for very low clock and data rates or very short connections, signal conductors must be driven by and terminated in their characteristic impedance to avoid signal reflections causing unacceptable signal integrity. Material properties and conductor dimensions result in the characteristic signal impedance of such conductors being centered on a value of about 50 ohms, or 100 ohms differentially. This means that signal transmission power would be quite high if the intrinsic signal rates and swings of the electronic circuits were widely used in a large system. EMI and mutual coupling between signals would also become difficult to manage. It is advantageous for noise, power, and system complexity reasons to include SERDES devices to significantly reduce the number of long-range signals required, increase bit rate to a more nearly optimum value and at the same time to reduce signal amplitude to a more nearly optimum value.

To compensate for distortion in the signal conductors for further enhanced transmission range and rate, SERDES devices typically add pre-emphasis to the transmitted signal and perform equalization on the received signal. To allow the same high-speed signal to carry both data and clock information, the transmitter encodes the signal and the receiver performs both clock recovery and data decoding.

It is clear from the above details that the key circuits used within a SERDES generally must have very high performance, tending to make them difficult to test and verify. Nevertheless, it is essential, both in manufacture and for fault location within operating systems, to perform such testing and verification quickly and efficiently. Built-In-Self-Test (BIST) methods make such testing much faster and more efficient and eliminate almost all hardware requirements outside of the devices which are to be tested. However, most present BIST testing techniques address only digital logic verification. Analog circuit behavior, however, is key to the purpose and capabilities of SERDES devices, particularly to the more advanced devices. There is a need for BIST testing of integrated SERDES devices with respect to performance verification of the primary analog blocks, i.e., clock recovery and transmission line compensation circuitry, which are usually the most critical and the most difficult circuits to design, test, and verify.

In increasing instances more advanced techniques such as adaptive linear equalization and adaptive DFE (Decision Feedback Equalization) are used to compensate for non-ideal transmission performance. Methods are also needed to enhance the standard, highly efficient digital BIST techniques so as to enable testing and verification of these high performance analog circuits with similar efficiency.

Embodiments disclosed herein eliminate the need for complex external testing to verify the analog performance of increasingly more important, complex, and higher bandwidth analog circuitry used for Electronic Dispersion Compensation (EDC). BIST capabilities are extended to include verification of analog circuitry and performance with similar efficiency to that achieved historically for digital circuitry.

### SUMMARY

In an embodiment, a testing method comprises: receiving a serial data signal in a receiver; applying compensation by the receiver to that received serial data signal to generate a compensated serial data signal; measuring properties of an eye diagram associated with the compensated serial data signal, wherein certain desired eye diagram properties are characterized by parameters indicative of pass/fail testing criteria for receiver compensation testing; comparing the measured eye diagram properties against the parameters; and generating a receiver testing conclusion signal output based on results of the comparison and indicating whether the applied compensation passes the testing criteria.

In an embodiment, a circuit comprises: a receiver that receives a serial data signal and includes circuitry which applies compensation to that received serial data signal to generate a compensated serial data signal; and an eye mapping circuit that measures properties of an eye diagram associated with the compensated serial data signal, wherein certain desired eye diagram properties are characterized by parameters indicative of pass/fail testing criteria for receiver compensation circuitry testing, the eye mapping circuit further comparing the measured eye diagram properties against the parameters and generating a receiver testing conclusion signal output based on results of the comparison and indicating whether the compensation circuitry of the receiver passes the testing criteria.

In an embodiment, a circuit comprises a receiver that receives a serial data signal and includes analog circuitry, the receiver functioning to generate a compensated serial data signal from the received serial data signal; a built-in self test circuit for testing the analog circuitry, the built-in self test circuit including: an eye mapping circuit that measures properties of an eye diagram associated with the compensated serial data signal, compares the measured eye diagram properties are against parameters and generates a self-test conclusion signal output based on results of the comparison and indicating whether the analog circuitry of the receiver passes testing criteria.

### BRIEF DESCRIPTION OF THE DRAWINGS

Preferred embodiments according to the present invention will now be described with reference to the Figures, in which like reference numerals denote like elements, and wherein:

FIG. 1 illustrates a basic configuration for a high speed SERDES (SERializer/DE-Serializer) architecture with eye mapping capability;

FIG. 2 illustrates an eye diagram and certain characteristic parameters associated therewith which are monitored by an eye mapping circuit;

FIG. 3 which shows a block diagram of a clock and data recovery (with eye monitor) circuit; and

FIG. 4 is a flow diagram illustrating a method of operation.

### DETAILED DESCRIPTION OF THE DRAWINGS

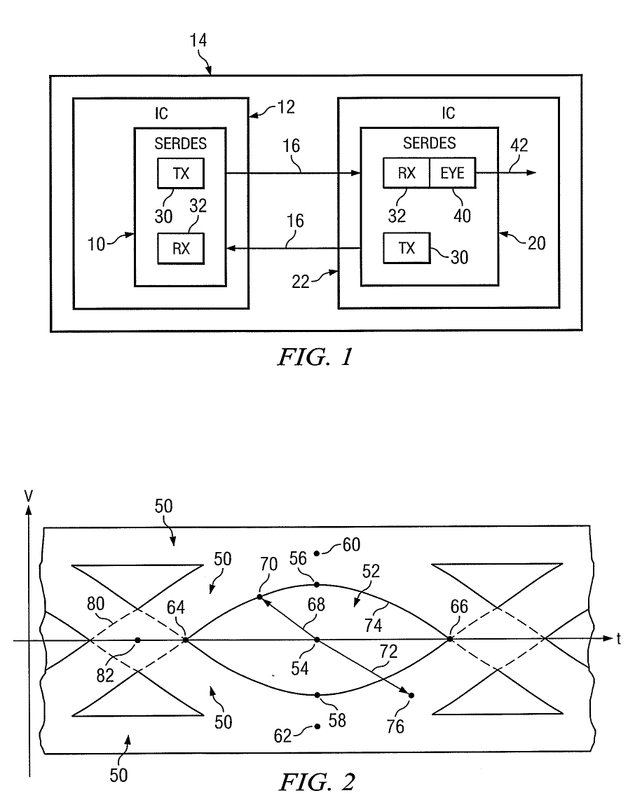

Reference is made to FIG. 1 which illustrates a configuration for a high speed SERDES (SERializer/DE-Serializer) architecture with eye mapping capability. A first SERDES 10 associated with a first integrated circuit 12 is coupled to communicate over a backplane 14 providing a plurality of serial communications links 16 with a second SERDES 20 associated with a second integrated circuit 22. Each SERDES 10 and 20 includes a transmitter (TX) circuit 30 and a receiver (RX) circuit 32. At least one, and preferably both, of the SERDES 10 and 20 further includes an eye mapping circuit 40 associated with the receiver circuit RX 32. This eye mapping circuit 40, as will be described herein, evaluates the received signal and determines whether the receiver circuitry, in particular its analog circuit components, is functioning properly. The eye mapping circuit 40 supports a form of built-in self testing as described herein and can generate a test result signal 42 indicative of the BIST testing result. This signal 42 can be processed on the integrated circuit 22, passed off the integrated circuit 22 to the backplane 14, and/or can drive feedback or other diagnostic or repair functionalities as desired.

The receiver circuit RX 32 primarily functions to perform receive clock and data recovery (CDR) operations with respect to a received serial data signal. The eye mapping circuit 40 associated with or within the receiver circuit RX 32 performs eye monitoring for BIST in a manner to be described. The serial data signal received by the receiver circuit RX 32 is, as is well known to those skilled in the art, first equalized in the frequency domain, then in the time domain (with DFE, for example), and generally for each significant change the gain is adjusted to achieve an amplitude value that lies within a desirable range. Consequently, the internal eye seen inside the receiver circuit RX 32 following compensation, for example by the eye mapping circuit 40, is generally more open than the eye of the received data signal if measured externally to the receiver (for example, at the input). The primary reasons for this are the lack of equalization and the superposition of the incoming signal with delayed reflections. There may also be further differences due to eye closure from internal jitter, amplitude noise and non-ideal sampling characteristics. Nonetheless, it will be recognized that if the eye mapping circuit 40 is used to perform eye monitoring on the recovered data signal (following, for example, time/frequency domain equalization by the receiver 32), then the quality of the measured eye is indicative of the quality of the operation of the analog clock and data recovery (CDR) circuitry operation of the receiver, including its associated compensation circuitry. The eye mapping circuit 40 can thus be used to perform Built-In-Self-Test (BIST) testing operations with respect to this receiver analog circuitry.

FIG. 2 illustrates an eye diagram and certain characteristic parameters associated therewith which are monitored/measured by the eye mapping circuit 40. The eye diagram or eye map as shown in FIG. 2 is just a time-voltage map showing where and by how much the data recovered differs from ideal versus the two offset time and voltage dimensions. It can also be considered to be a map of the combined set of actual signal trajectories, or at least portions of them having some specific probability of occurring or rate of mismatch (BER) relative the data channel. Since the eye mapping parameters are measured by the eye monitor using circuitry that is well matched to that used to recover the actual data, the map gives an accurate representation of the timing and amplitude margins of the actual data recovery channel. The regions 50 represent the actual data traces of the signal. As equalization improves, the traces present within the regions 50 will become more tightly grouped. In other words, the bands for the regions 50 defined by the traces will become narrower. Region 52 within the eye diagram or eye map of FIG. 2 is the inner eye opening and the point 54 is the center eye point. The goal of the equalization processes is to expand the size of, and better define, the inner eye opening 52.

Points 56 and 58 are the upper and lower amplitude points, respectively, of the inner eye opening 52. In a preferred implementation, these amplitude points are aligned, along the time t axis, with the location of the center eye point 54. The amplitude values associated with the upper and lower inner eye value points 56 and 58 are measured by the eye mapping circuit 40 and need to be sufficiently large (in magnitude away from the center eye point 54) to ensure that sampler offset and external interference are unlikely to cause significant performance degradation.

Points 60 and 62 are the upper and lower amplitude points, respectively, of the median eye value for the regions 50 representing a logical 1 and a logical 0, respectively. Again, in a preferred implementation, these amplitude points are aligned, along the time t axis, with the location of the center eye point 54. The amplitude values associated with the upper and lower median eye value points 60 and 62 are measured by the eye mapping circuit 40. The ratio of the inner eye amplitude (at points 56 and 58) to the median eye amplitude (at points 60 and 62) is calculated by the eye mapping circuit 40 and this calculated ratio gives a value representative of the percentage eye opening which is a good measure indicative of how well compensation in the receiver is correcting for signal dispersion and media losses.

Points 64 and 66 are the left and right timing (or phase) corners, respectively, of the inner eye opening 52. In a preferred implementation, these timing points are aligned, along the voltage V axis, with the location of the center eye point 54. The timing values associated with the left and right corner points 64 and 66 are measured by the eye mapping circuit 40 and define the margins available in the receiver to handle jitter and phase noise.

Although the points 56, 58, 64 and 66 represent the extremes or corners of the inner eye opening 52, it will be understood that the eye mapping circuit 40 can function to measure any point along the perimeter 74 of the eye opening 52. This functionality is represented by the illustrated measurement vector 68 of the eye mapping circuit 40 which is measuring an exemplary point 70 along the perimeter 74 of the eye opening 52. Still further, although points 60 and 62 represent the median eye values aligned in time with the center eye point 54, it will be understood that the eye mapping circuit 40 can function to measure any median point of a desired region 50. This functionality is represented by the illustrated measurement vector 72 of the eye mapping circuit 40 which is measuring the point 76 at the median for a different band for a region 50 defined by the traces and which is offset in time from the center eye point 54. The information concerning points 70 and/or 76 can be used in a manner similar to, or in addition to, the information concerning points 56, 58, 64 and 66 in order the characterize the quality of the inner eye opening 52 and eye diagram/map.

The clock and data recovery functionality within the receiver circuit RX 32 monitors the diamond-shaped region 80 of the eye diagram/map where two of the bands for the regions 50 defined by the traces (and representing data transition between high and low) intersect in order to identify the clock recovery lock point 82 which is preferably centered in time and voltage within the region 80.

The eye-mapping circuit 40 is particularly effective for implementing a BIST functionality because it can extract simple characteristic information for the inner eye opening 52 that can be directly used as pass/fail criteria during verification (such as in BIST testing) of analog compensation and CDR circuitry within the receiver. Without such simple direct information it is much more difficult to determine if high-speed analog circuitry within the receiver 32 is performing properly, and even more difficult to include the necessary tests within an automatic BIST scheme.

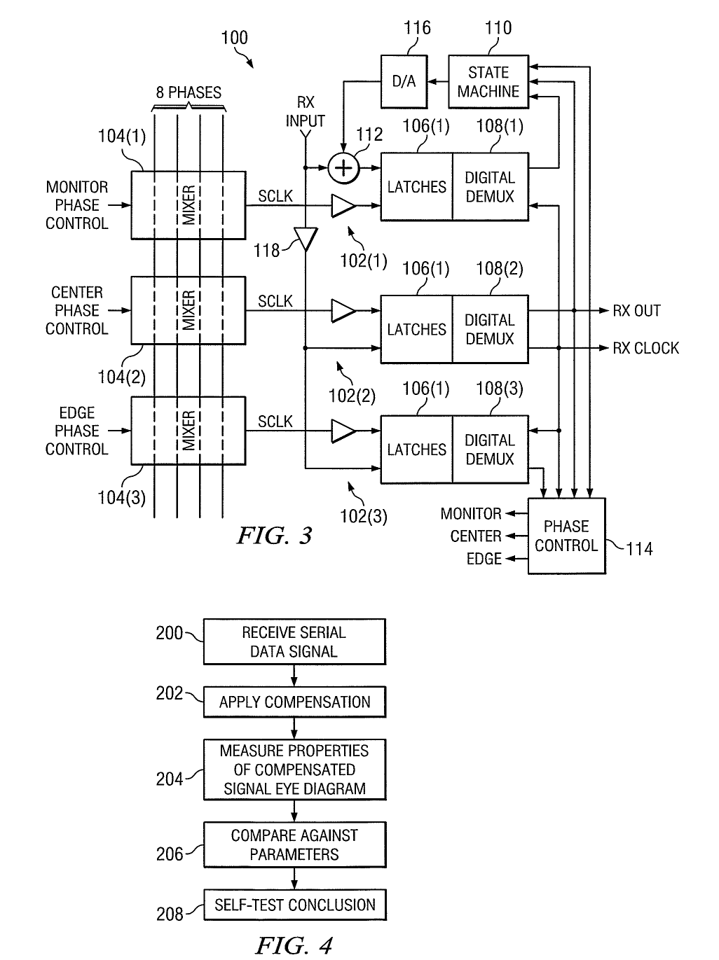

Reference is now made to FIG. 3 which shows a block diagram of a clock and data recovery (with eye monitor) circuit 100 which can be used in the receiver 32 and eye monitor 40 of FIG. 1. Clock, data and eye recovery are closely related functions and are each based on the use of well matched data sampling channels 102. Each channel 102 comprises a phase mixer 104 to precisely control the bit sampling clock SCLK, fast latches 106 to sample the input signal (from RX INPUT), and a digital demultiplexer 108 to reduce the bit-clock rate to a word-clock rate that is effective and convenient for the data processing necessary for CDR and eye monitoring. One channel 102(1) including mixer 104(1), latches 106(1) and demux 108(1) provides a monitor channel or monitor phase. Another channel 102(2) including mixer 104(2), latches 106(2) and demux 108(2) provides a center channel or center phase. A last channel 102(3) including mixer 104(3), latches 106(3) and demux 108(3) provides an edge channel or edge phase. The center channel 102(2) outputs the recovered data (RX OUT) and recovered clock (RX CLOCK). The recovered clock is supplied to the monitor and edge channels 102(1) and 102(3) as well as to the phase control circuit 114 which generates phase control signals for application to the mixers 104 for each of the channels 102 to select clock SCLK phase.

For clock and data recovery, the process performed by the circuit 100 is well known in the art. Mismatches for each sample taken by the edge channel 102(3) in the diamond shaped crossover region 80 leading to each inner eye opening 52, relative to the equivalent sample taken by the center channel 102(2) near the center of the eye (where data integrity is high), are added to a sum, while those for each edge sample taken in the crossover region trailing the eye are subtracted from the sum. The edge sampling points are moved right or left when the sum reaches a selectable positive or negative limit, causing them to be strongly drawn toward and held near the median crossover position at point 82.

While the center data channel 102(2) maintains minimum voltage offset and tight timing relative the data signal through the action of the clock recovery control loop through phase control circuit 114, the eye monitor (the monitor phase or channel 102(1)) is able to separately adjust its timing and voltage offsets relative to the data channel 102(2) to explore the eye at other positions than the center. For eye monitoring, a similar mismatch counting method with the center phase channel 102(2) is used with the monitor channel 102(1) acting in place of the edge channel 102(3) in accordance with the process previously described. However, not only timing offset but also voltage offsets of the monitor channel 102(1) can be selectively and controllably swept until a mismatch count closest to some specific and selectable value is obtained. Such a value lies as close as can be determined to a fixed BER contour where the BER for the contour is equal to the selected mismatch count divided by the total number of comparisons performed. With random data, or any data with reasonable transition density and a balance of logical 0's and 1's, the potential mismatch count is essentially 50% of the number of comparisons performed.

The eye monitor can also perform correlation sums between mismatches for each eye monitor bit and other nearby bits sampled by the center channel 102(2). If timing is set to mid-eye and voltage offset is set to obtain BER close to 25% (½ of the maximum), these correlation sums are maximized and will tend to give the polarity of the ISI coefficients and even some indication of their magnitude. Basically, for such a median voltage offset, bits of the corresponding polarity (50% of the total bits) will sometimes have an amplitude just above the offset and sometimes just below it, causing the ISI to be the deciding factor in whether a logical ‘0’ or a ‘1’ is detected by the eye monitor sampler (circuits 106 and 108 in the monitor channel 102(2)). Any bit-to-bit comparisons that are dependent on actual ISI will sum in a corresponding manner, while any that are not will sum roughly to zero over time due the relatively random and balanced nature of the data. By adjusting each equalization coefficient in the direction to reduce the corresponding component of the ISI toward zero, the settings are systematically moved toward a condition of minimum ISI.

It is thus recognized that all three channels 102 are intended to be as well matched as possible. By making the center and edge channels 102(2) and 102(3) identical, the actual center channel 102(2) sampling points will be spaced in time from the edge channel 102(3) sampling point by a value exactly equal to the actual timing difference between the edge and center channel clocks SCLK no matter what specific timing characteristics both may have in common. Since the alignment process places the true edge channel 102(3) sampling point at the median data crossover points as discussed above, and since center channel 102(2) timing is generated by adding a digital offset to the edge channel 102(3) timing setting, the true center channel 102(2) sampling point relative the crossover points is as nearly as possible equal to the applied digital offset. Similarly, the eye monitor channel 102(1) timing is given by its digital offset value relative to the center channel 102(2) sampling point except for the delay difference in the analog signal between the limiting amp 118 in the CDR path versus the summer 112 in the eye monitor path. In the eye monitor channel 102(1), an offset voltage produced by a digital to analog converter D/A 116 under the control of a state machine 110 is added 112 to the signal before it reaches the eye monitor data sampling latches. Hence the monitor channel 102(1) can selectively probe anywhere inside or outside the eye in both timing and voltage dimensions and count the mismatches (BER) at any point over an extended time. Using this technique, the eye mapping circuit 40 can make measurements of the points 56, 58, 60, 62, 64 and 66 for the BIST testing purposes discussed above.

A differential CML summer 112 used to apply voltage offset to the sampled data in the eye monitor channel 102(1) causes some inevitable differences in this channel. However, this and any other channel-to-channel timing or voltage differences can be calibrated out by applying center channel 102(2) offset in both directions from the nominal until some particular BER results. The proper center channel 102(2) offset is the value midway between two settings that are found to give that same BER, however, sometimes it might be beneficial to add some further small timing offset to compensate for eye asymmetry if it is significant. Once the center channel 102(2) offset is corrected as above, the offset in the midpoint between the left and right eye edges obtained by the eye monitor (using channel 102(1)) for roughly the same BER value reveals its actual offset. Eye monitor absolute voltage offset can similarly be determined from upper and lower edge measurements using either a random data pattern or a fixed pattern with mirror symmetry, i.e., a pattern that is unchanged by polarity inversion.

To maintain linear signal conditions while having the ability to apply an offset voltage that is as large as the full signal voltage, both the input signal and the offset are attenuated to half amplitude at the inputs to the summer 112. The linear sum is then passed to a second limiting stage within summer 112 which provides at least 2× gain and limits the output amplitude in the same manner as the limiting amp 118 in the path to the edge and center channels 102.

The phase control signals output from the phase control circuit 114 comprise digital timing offsets. The phase mixers 104 retime their phase select inputs so that any glitches resulting from the use of digital timing offsets (as opposed to actual phase settings) will be eliminated as the alignment process drives the phase of the edge channel 102(3) along a potentially erratic path tracking jitter and frequency offset. The modulation is applied to the other channels 102(1) and 102(2) as well, and therefore only relatively fixed phase differences need to be supplied for those channels.

It will thus be recognized that the eye mapping circuit 40 reuses some circuit design and layout already available for the primary data sampler and simply adds circuitry for adding a voltage offset. It will also be noted that the eye mapping circuit 40 is power efficient because it is only needed occasionally, and thus can be powered down when not needed.

The Inter-Symbol-Interference correlation sums extracted for DFE adaptation are very valuable, even if DFE is not used, since they indicate directly which specific coefficients are not optimally adjusted, and in which direction. To obtain the median eye opening, also needed for adaptive DFE, and to efficiently measure other properties of the eye that can be used to determine if the analog circuitry is functioning properly, the eye mapping circuit 40 includes efficient search routines that allow a few simple commands to request essential information and place that information into a readily accessible register when found.

As discussed, the receiver functionality used for making median amplitude and bit-to-bit correlation measurements needed by adaptive compensation algorithms uses its own data sampler (channel 102(1)) identical to the primary data sampler (channel 102(2)) but with ability to vary its input offset voltage. By varying this offset voltage while comparing the data from this sampler bit-for-bit with that from the main data sampler, the median amplitude of 0's and 1's can be accurately determined. The ability to search for and find the median bit amplitudes can be easily extended by the eye mapping circuit 40 to searching for and finding the vertical opening of the inner or outer eye and providing them in digital form. Since these eye opening measurements are made at the data sampler input after analog circuitry has applied pre-emphasis, linear equalization, and DFE, they are ideal for verification of these compensation circuits whose primary purpose is to optimize these same eye openings. By adding the ability to also offset the sampling point phase (timing) from that of the main data sampler it is possible to search for and find the horizontal opening of the inner eye and provide this information in digital form. The result is a general-purpose eye-mapping circuit 40 block that can make measurements of any point on the eye boundary without affecting the bit error rate (BER) of the primary data channel 102(2). As discussed above, implementation of this eye-mapping circuit 40 block does not require much additional circuitry than that already present in the receiver.

The eye-mapping circuit 40 is particularly effective for BIST because it can extract simple information on the eye opening that can be used directly as pass/fail criteria during verification of analog compensation and CDR circuitry in each of their key settings. Without such simple direct information it is very much more difficult to determine if high-speed analog circuitry is performing properly, and even more difficult to include the necessary tests within an automatic BIST scheme. The actual sequence of commands needed to perform such verification tests, and the pass and fail criteria for each test, can be controlled, with the programmable pass/fail criteria being optimized for the application, the test environment, and other factors.

The characteristic information regarding the eye which is found by the eye-mapping circuit 40 can be stored into accessible registers 42 quickly and efficiently with minimum demands on overall system control. It is preferable to have built-in algorithms for the eye mapping circuit 40 to search for eye positions meeting specified criteria, and to accumulate ISI (Inter-Symbol-Interference) statistics which provide even more detail. Often many tens or hundreds of thousands of bits of data must be analyzed to obtain the desired results for each search, so trying to do this indirectly outside the eye-mapping circuit 40 would be prohibitive. The built-in algorithms allow a single command to select and initiate one of many different sequences of data processing involving a large amount of data being compressed into a small amount of critical information that is placed in readily accessible registers.

The most useful built-in search algorithms can be classified into 3 groups:

1) Inner Eye Search: this search finds two vertically or horizontally opposing points (dimensions of voltage and/or phase) on the inner edge perimeter 74 of the eye 52 defined by the minimum detectable mismatch rate between a selectable number of bits from the eye-mapping circuit 40 and equivalent bits from the main data channel. This means that the voltage trajectories of all bits observed were just beyond both of these points. The search scan can be in either the voltage offset dimension or the phase offset dimension, while the offset in the other dimension may be set to any desired value, a ‘0’ value offset meaning a scan through the center point 54 of the eye. To maximize efficiency, a binary search technique may be used, and each test of offset will be terminated as soon as a mismatch occurs or when the selected “adequate” number of matching bits is reached.

2) Outer Eye Search: this search finds two opposing points on the edge of the eye defined by a selectable, larger than minimum mismatch rate between bits from the eye-mapping circuit 40 and equivalent bits from the main data channel. A large mismatch rate, approaching 50%, (the maximum for random data), will indicate the point is outside most of the voltage trajectories for all bits observed with the corresponding polarity. A small mismatch rate, approaching 0%, will indicate the point is inside most of the voltage trajectories for all bits observed with the corresponding polarity. A 25% mismatch rate will indicate the point is at the median of the trajectories for all bits observed with the corresponding polarity. A median search in the voltage dimension with zero phase offset gives a good measure of the true signal amplitude as well as the optimum points for performing ISI correlation sums, as described below, since these points tend be where the eye trajectories are most densely and uniformly packed.

3) ISI Correlation Sums: ISI is the interference from one bit on another bit, usually a bit trailing by a small number of bit periods or UI. Hence ISI is defined by coefficients for the signal amplitude from each transmitted bit present at bit times separated from that bit by . . . −1, 1, 2, 3, . . . UI. It is caused by dispersion of signal energy by losses and reflections due to impedance discontinuities in the transmission line, most of which tend to add delay, yielding mainly positive coefficients. If data is sampled close to the mean or median amplitude of each bit, the ISI and any other minor interference will often tip the balance between a logical ‘0’ or a ‘1’ being detected. By correlation (EXOR) of these affected bits with known bits 1, 2, 3 . . . UI earlier (or later), the presence, and to some extent the magnitude, of the corresponding ISI coefficient will be apparent over a large sample size. All of the unrelated noise and interference will average to zero after being randomized by correlation with the random bit stream. The eye mapping circuit 40 can generate all the required ISI correlation sums in parallel. With its offset and sampling circuitry it can measure the median amplitudes, apply perfectly matching offsets, and generate the bit stream containing the effects of ISI. It has direct access to the uncorrupted bit stream from the main data channel, and the same counting circuitry used for the eye scans can be used to count out a similar number of bits to be included in the sums. It needs only to include correlation logic and a summation register for each coefficient, and make the registers accessible via the control-bus.

ISI correlation sums have multiple purposes because they provide raw information on the unwanted influence of each bit on other bits, i.e., the compensation error. They can be used in testing to indicate if and how well compensation circuitry has or has not corrected for signal dispersion and other distortion, or to verify that a particular analog setting has the proper effect whether or not it is set optimally. They can be used by an internal or by an external algorithm to automatically adapt DFE coefficients to optimum values. If a control path from the eye-mapping circuit 40 back to a FIR equalizer or other equalizer type at the source (TX) of the signal were available, they could be used to automatically adapt its coefficients. They can be used indirectly through adapted DFE coefficients to adapt the settings of a linear equalizer to improve performance and reduce the burden on DFE circuitry. They could also be used directly to adapt linear equalizer settings, however, in this case they need to be carefully weighted and combined since each sum will tend to reflect the settings differently.

The simplest and most accurate information on the performance of Electronic-Dispersion-Control circuitry, which is largely analog, is the openness of the receive data eye at the primary data sampler. By adding phase control to the second data-sampler which is already needed for adaptive DFE, the eye-mapping circuit 40 possesses the capability to characterize the essential properties of the receive data eye with a few simple parameters. These parameters are then used as pass/fail criteria for BIST of the high performance EDC circuitry.

Reference is now made to FIG. 4 which is a flow diagram illustrating a method of operation. In step 200, a serial data signal is received. In step 202, compensation is applied to that received serial data signal to generate a compensated serial data signal. Compensation in this contest may comprise, for example, frequency and/or time domain compensation. The performed compensation may include some form of equalization performed by the signal receiver prior to data recovery. In step 204, measurement is made of the properties of the eye diagram associated with the compensated serial data signal. The essential or desired properties of an eye diagram can be characterized by a few parameters which are indicative of pass/fail criteria for testing (such as BIST). For example, these parameters may be indicative of satisfactory operation of the analog circuitry associated with the signal receiver, in general, or the included compensation functionality, in particular. In step 206, the measured properties for the eye diagram of the compensated serial data signal are compared against the parameters. To the extent any measured property for the eye diagram of the compensated serial data signal fails to satisfy the parameters (for the essential or desired property), the test is failed. Conversely, to the extent any measured property for the eye diagram of the compensated serial data signal meets the parameters (for the essential or desired property), the test is passed. After all desired measured properties have been evaluated, a self-test conclusion is reached and a signal indicative of that conclusion is generated in step 208. Because of the correlation between the quality of the measured eye and the operation of the analog circuitry within the receiver, this conclusion may be considered a BIST that is indicative of whether the analog circuitry is functioning properly.

Reference is once again made to FIG. 2, and more specifically the points 56 and 58 which are the upper and lower amplitude points, respectively, of the inner eye opening 52. In step 204, the amplitude values associated with the upper and lower inner eye points 56 and 58 are measured. An essential or desired property of an eye diagram would set corresponding pass/fail amplitudes for the points 56 and 58 as the parameters. In step 206, the measured amplitude values (properties) for the points 56 and 58 are compared against these parameters. Only if the measured amplitude values exceed (in magnitude) the parameter values would the test be passed, providing insurance that sampler offset and external interference are unlikely to cause significant performance degradation. The self-test conclusion reached in step 208 would thus be that the analog circuitry of the receiver is functioning properly.

Reference is now made to the points 64 and 66 which are the left and right timing (phase) corners, respectively, of the inner eye opening 52. In step 204, the timing location values associated with the left and right corner points 64 and 66 are measured. An essential or desired property of an eye diagram would set corresponding pass/fail timing locations for the points 64 and 66 as the parameters. In step 206, the measured amplitude values (properties) for the points 56 and 58 are compared against these parameters. Only if the measured timing location values exceed (in magnitude) the parameter values would the test be passed, providing insurance that sufficient margins available in the receiver to handle jitter and phase noise. The self-test conclusion reached in step 208 would thus be that the analog circuitry of the receiver is functioning properly.

Reference is now made to points 60 and 62 which are the upper and lower amplitude points, respectively, of the median eye value, along with points 56 and 58 which are the upper and lower points, respectively, of the inner eye opening 52. In step 204, the amplitude values are measured for the upper and lower median eye points 60 and 62 as well as the upper and lower inner eye points 56 and 58. Step 204 would further include, for this implementation, the calculation of a first ratio of the upper inner eye point 56 amplitude to the upper median eye point 60 amplitude, and a second ratio of the lower inner eye point 58 amplitude to the lower median eye point 62 amplitude. An essential or desired property of an eye diagram would set corresponding pass/fail ratios as the parameters. In step 206, the measured first and second ratios are compared against the corresponding parameters. Only if the measured ratios exceed (in magnitude) the parameter values would the test be passed, providing insurance that the compensation functionality within the receiver is correcting for signal dispersion and media losses. The self-test conclusion reached in step 208 would thus be that the analog circuitry of the receiver is functioning properly.

While this detailed description has set forth some embodiments of the present invention, the appended claims are sufficiently supported to cover and will cover other embodiments of the present invention which differ from the described embodiments according to various modifications and improvements apparent to those skilled in the art.

What is claimed is:

1. A testing method, comprising:
receiving a serial data signal in a receiver;
applying compensation by the receiver to that received serial data signal to generate a compensated serial data signal;
measuring properties of an eye diagram associated with the compensated serial data signal, wherein certain desired eye diagram properties are characterized by parameters indicative of pass/fail testing criteria for receiver compensation testing;
comparing the measured eye diagram properties against the parameters; and
generating a receiver testing conclusion signal output based on results of the comparison and indicating whether the applied compensation passes the testing criteria.

2. The method of claim 1 wherein applying compensation comprises applying equalization to the received serial data signal.

3. The method of claim 1 wherein measuring properties comprises measuring signal amplitudes at upper and lower points of an inner eye opening for the eye diagram, the certain desired eye diagram properties comprising certain inner eye opening amplitude values.

4. The method of claim 1 wherein measuring properties comprises measuring timing location at left and right corners of an inner eye opening for the eye diagram, the certain desired eye diagram properties comprising certain inner eye opening timing location values.

5. The method of claim 1 wherein measuring properties comprises:
measuring signal amplitudes at upper and lower median eye amplitudes for the eye diagram;
measuring signal amplitudes at upper and lower points of an inner eye opening for the eye diagram; and
calculating ratios of inner eye opening amplitude to median eye amplitude;
the certain desired eye diagram properties comprising certain ratio values.

6. The method of claim 1 wherein the receiver testing conclusion signal is a built-in self test signal for the receiver.

7. A circuit, comprising:
a receiver that receives a serial data signal and includes circuitry which applies compensation to that received serial data signal to generate a compensated serial data signal;
an eye mapping circuit that measures properties of an eye diagram associated with the compensated serial data signal, wherein certain desired eye diagram properties are characterized by parameters indicative of pass/fail testing criteria for receiver compensation circuitry testing, the eye mapping circuit further comparing the measured eye diagram properties against the parameters and generating a receiver testing conclusion signal output based on results of the comparison and indicating whether the compensation circuitry of the receiver passes the testing criteria.

8. The circuit of claim 7 wherein the compensation comprises equalization.

9. The circuit of claim 7 wherein the eye mapping circuit measures signal amplitudes at upper and lower points of an inner eye opening for the eye diagram, the certain desired eye diagram properties comprising certain inner eye opening amplitude values.

10. The circuit of claim 7 wherein the eye mapping circuit measures timing location at left and right corners of an inner eye opening for the eye diagram, the certain desired eye diagram properties comprising certain inner eye opening timing location values.

11. The circuit of claim 7 wherein the eye mapping circuit:
measures signal amplitudes at upper and lower median eye amplitudes for the eye diagram;
measures signal amplitudes at upper and lower points of an inner eye opening for the eye diagram; and
calculates ratios of inner eye opening amplitude to median eye amplitude;
the certain desired eye diagram properties comprising certain ratio values.

12. The circuit of claim 7 wherein the receiver testing conclusion signal is a built-in self test signal for the receiver.

13. The circuit of claim 7 wherein the eye mapping circuit comprises:
a center phase channel;
an edge phase channel;
a monitor phase channel; and
a phase control circuit generating phase control signals for application to each of the center, edge and monitor phase control channels, the phase control signals selecting phase offsets for sampling operations performed on the compensated serial data signal in each channel; and
a control circuit which selectively applies a voltage offset to the compensated serial data signal prior to input to the monitor phase channel.

14. The circuit of claim 13 wherein the selected phase offset and selected voltage offset specify a certain property of the eye diagram associated with the compensated serial data signal to be measured.

15. A circuit, comprising:
a receiver that receives a serial data signal and includes analog circuitry, the receiver functioning to generate a compensated serial data signal from the received serial data signal;
a built-in self test circuit for testing the analog circuitry, the built-in self test circuit including:
an eye mapping circuit that measures properties of an eye diagram associated with the compensated serial data signal, compares the measured eye diagram properties are against parameters and generates a self-test conclusion signal output based on results of the comparison and indicating whether the analog circuitry of the receiver passes testing criteria.

16. The circuit of claim 15 wherein the analog circuitry is equalization circuitry for generating the compensate serial data signal.

17. The circuit of claim 15 wherein the eye mapping circuit measures signal amplitudes at upper and lower points of an inner eye opening for the eye diagram, and the parameters specify desired inner eye opening amplitude values indicative of passing the built-in self test.

18. The circuit of claim 15 wherein the eye mapping circuit measures timing location at left and right corners of an inner eye opening for the eye diagram, and the parameters specify desired inner eye opening timing location values indicative of passing the built-in self test.

19. The circuit of claim 15 wherein the eye mapping circuit:
measures signal amplitudes at upper and lower median eye amplitudes for the eye diagram;
measures signal amplitudes at upper and lower points of an inner eye opening for the eye diagram; and
calculates ratios of inner eye opening amplitude to median eye amplitude;
wherein the parameters specify desired ratio values indicative of passing the built-in self test.

20. The circuit of claim 15 wherein the parameters are pass-fail criteria for the built-in self test.
